(19) United States
(12) Patent Application Publication
(10) Pub. No.: US 2008/0030954 A1
(43) Pub. Date: Feb. 7, 2008

(54) Computer casing with air channel for dissipating heat effectively

(76) Inventor: Kun-Hsiang Shieh, Taipei Hsien (TW)

Correspondence Address: KUN-HSIANG SHIEH, 235 Chung - Ho, Box 8-24, Taipei, omitted

(21) Appl. No.: 11/489,950

(22) Filed: Jul. 20, 2006

(51) Int. Cl. H05K 7/20

(52) U.S. Cl. 361/700

(57) ABSTRACT

A computer casing comprises a front plate and a back plate; two sides of the front plate and back plate being installed with a first lateral plate and a second lateral plate; a bottom plate being installed at a bottom side of the casing; an accessing unit installed at an inner corner side of the front plate and adjacent to the first lateral plate; a bottom of the accessing unit being corresponding to the grid holes of the bottom plate; an isolating plate installed at an inner surface of the second lateral plate; an inner space of the casing being formed with an air channel; a first fan being installed upon the back plate; output wires of a power supply serving to supply power to the motherboard and the accessing unit; and a second fan is installed on the through hole of the isolating plate corresponding to the motherboard.

### FIELD OF THE INVENTION

The present invention relates to a computer casing, and in particular to a computer casing with an air channel for dissipating heat effectively wherein an interior space of the computer casing is divided to have a novel arrangement, in that an independent air channel is formed so that external air can be guided thereinto and drain out along the channel and thus heat generated in the casing can be dissipating effectively.

### BACKGROUND OF THE INVENTION

Referring to FIGS. 1 and 2, the prior art computer casing 10, 20 is installed with an accessing unit 11, 21. The back plate 12, 22 is formed with a plurality of slots 13, 23 corresponding to the type of the motherboard (not shown, such as ATX, Baby ATX). Other space provides with two via holes 14, 24 for installing a fan and a power supply 13, 23. However the prior art has the following disadvantages.

An interior of the casing 10, 20 is a sealed space. External cool air cannot flow thereinto so that heat of the elements (such as integrated circuit) cannot be well dissipated out.

Moreover the power supply 15, 25 is installed at a space other than the space having the back plate 12, 22, slots 13, 23 and the fan via hole 14, 24. When a large scale motherboard (such as ATX) is installed in the casing 10, the back plate 12 is needed to arrange seven slots 13 so that the space of the back plate 12 is insufficient. Thus only small size power supply 15 (such as Micro Power Supply can be installed therein) which has a lower power output and is not a main trend of market. Thereby it is difficult to have the kind of power supply and it is expensive. On the contrary, if PS/2 power supply is installed on the back plate 12, it has a large size so that only small size motherboard (such as Baby ATX) with three slots 23 can be installed in the casing 3. Generally, such kind of motherboard has an All-in-One design so that it is not popular and is expensive.

Thereby the prior art is not preferred in heat dissipation and is not economic. This is a trouble to the manufacturers and users.

### SUMMARY OF THE INVENTION

Accordingly, the primary object of the present invention is to provide a computer casing, wherein an interior space of the computer casing is divided to have a novel arrangement, in that an independent air channel is formed so that external air can be guided thereinto and drain out along the channel and thus heat generated in the casing can be dissipating effectively.

To achieve above objects, the present invention provides a computer casing which comprises a front plate and a back plate; the back plate being installed with a plurality of slots; two sides of the front plate and back plate being installed with a first lateral plate and a second lateral plate; a bottom plate being installed at a bottom side of the casing; an accessing unit installed at an inner corner side of the front plate and adjacent to the first lateral plate; a bottom of the accessing unit being corresponding to the grid holes of the bottom plate; an isolating plate installed at an inner surface of the second lateral plate; a top end of the isolating plate being extended with a folded surface; a front end of the isolating plate being installed with an enhancing plate; a periphery of the isolating plate being adhered to the second lateral plate; the bottom plate, the front plate and the back plate; an inner space of the casing being formed with an air channel; the isolating plate being formed with a via hole and a through hole; the via hole being at a front end of the isolating plate near the front plate; the through hole being at a rear side of the isolating plate corresponding to the position of a motherboard; a first fan being installed upon the back plate; a power supply; output wires of the power supply serving to supply power to the motherboard and the accessing unit; and the motherboard being positioned at a spaced enclosed by the accessing unit, power supply and the isolating plate; a second fan is installed on the through hole of the isolating plate corresponding to the motherboard.

The various objects and advantages of the present invention will be more readily understood from the following detailed description when read in conjunction with the appended drawing.

### BRIEF DESCRIPTION OF THE DRAWINGS

FIG. 1 shows the arrangement of the prior art computer casing.

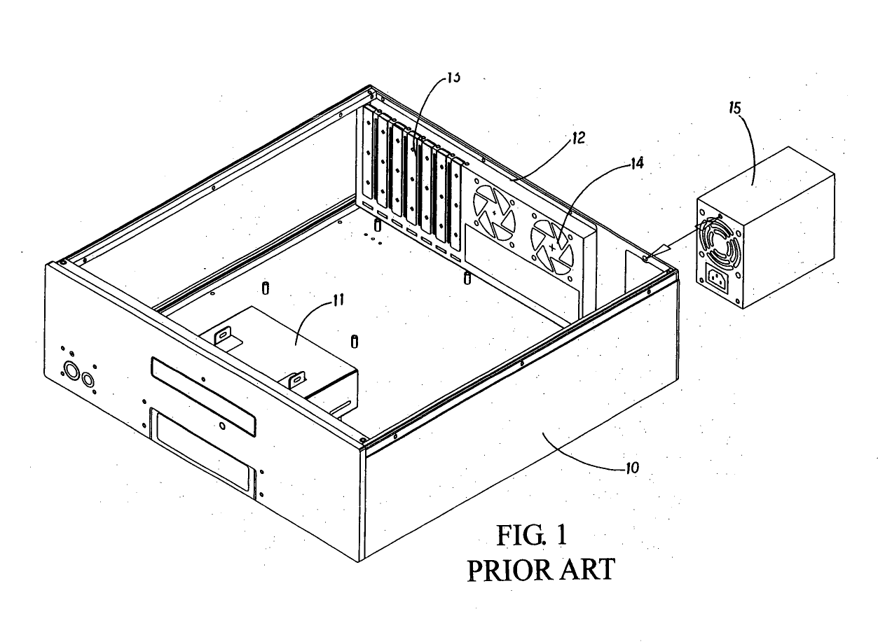

FIG. 2 shows the arrangement of another prior art computer casing.

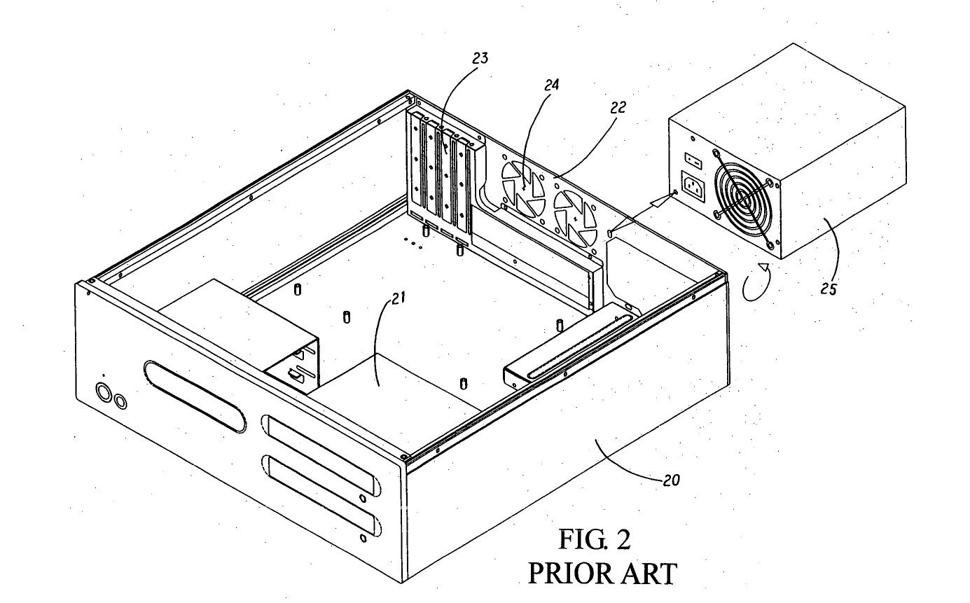

FIG. 3 is an exploded perspective view of the present invention.

FIG. 4 is a schematic view of the present invention.

FIG. 5 is a schematic view showing the airflow path of the present invention.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

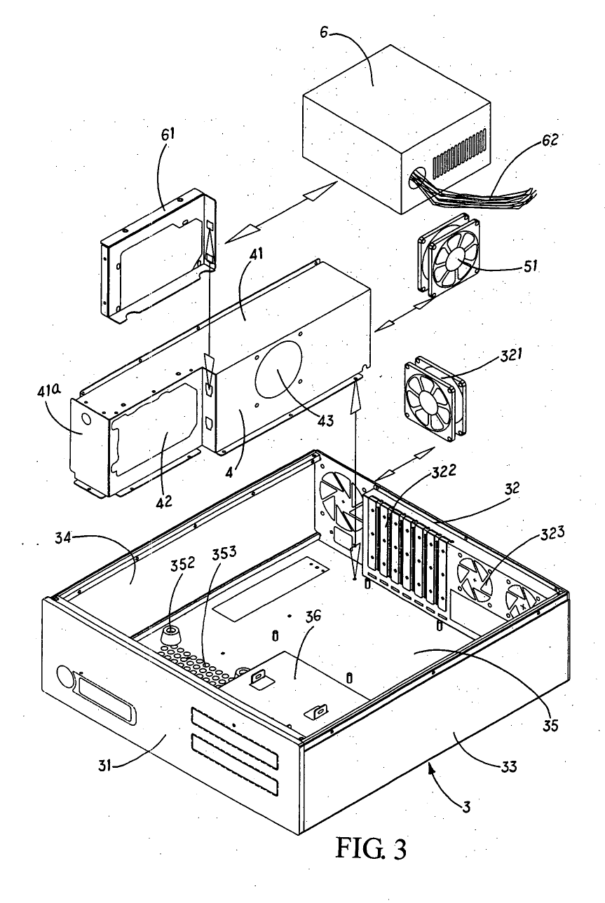

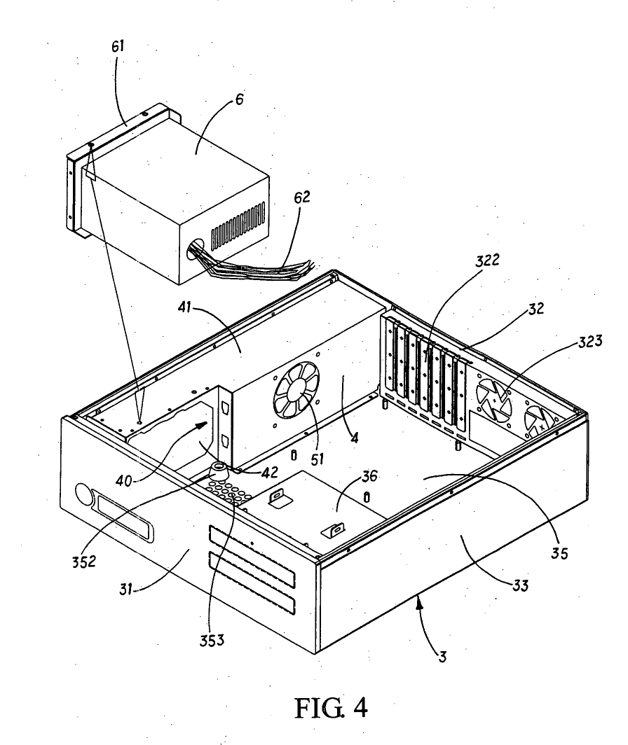

Referring to FIGS. 3 and 4, the improvement of a computer casing according to the present invention is illustrated. The casing 3 of the present invention has the following elements.

A front plate 31 is included. A back plate 32 is installed with a plurality of slots 322. Two sides of the front plate 31 and back plate 32 are installed with a first lateral plate 33 and a second lateral plate 34. A cover (not shown) serves to cover the space enclosed by the front plate 31, back plate 32, first lateral plate 33 and second lateral plate 34.

A bottom plate 35 has a plurality of grid holes 351 and a plurality of pads 352 and net holes 353 at one side thereof.

An accessing unit 36 installed at an inner corner side of the front plate 31 and adjacent to the first lateral plate 33. A bottom of the accessing unit 36 is corresponding to the grid holes 351 of the bottom plate 35.

An isolating plate 4 is installed at an inner surface of the second lateral plate 34. A top end of the isolating plate 4 is extended with a folded surface 41. A periphery of the isolating plate 4 is adhered to the second lateral plate 34, the bottom plate 35, the front plate 31 and the back plate 32. An inner space of the casing 3 is formed with an air channel 40. The isolating plate 4 is formed with a via hole 42 and a through hole 43. The via hole 42 is at a front end of the isolating plate 4 near the front plate 3 1. The through hole 43 is at a rear side of the isolating plate 4 corresponding to the position of a motherboard 5.

A fan 321 is installed upon the back plate 32.

A power supply 6 is preferably a PS/2 power supply. A lateral side of the power supply 6 has a fan (not shown) corresponding to the via hole 42 and has a frame 61 which is connected to the via hole 42. The output wire 62 of the power supply 6 serves to supply power to the motherboard 5 and the accessing unit 36. A bottom of the power supply 6 is formed with a fan (not shown) and is installed at position corresponding to the pads 352 and net holes 353 of the bottom plate 35. The pads 352 make the power supply 6 being at a position higher than the net holes 353.

The motherboard 5 is positioned at a spaced enclosed by the accessing unit 36, the power supply 6 and the isolating plate 4. A fan 51 is installed on the through hole 43 of the isolating plate 4 corresponding to the motherboard 5.

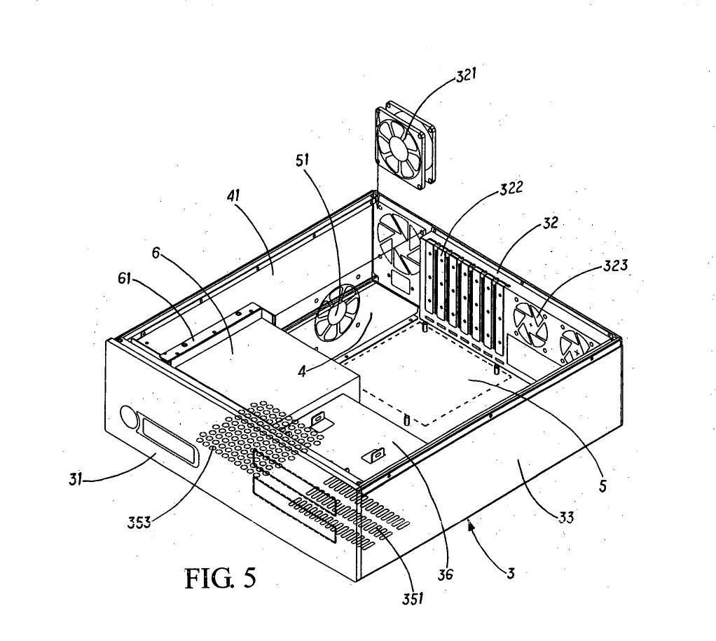

Thus, in assembly, the frame 61 of the power supply 6 is installed at the via hole 42 of the isolating plate 4 and is at an inner surface of the front plate 3 1. When the power supply 6 is actuated, the external air is guided into the casing 3 and then enters into the casing 3 through the net holes 353 and grid holes 351 of the bottom plate 35 (referring to FIG. 5) so as to dissipate heat of the circuit or other electronic elements in the casing 3. The air flows out from the fan 321 at the rear side of the air channel 40. The fan (not shown) at the rear side of the power supply 6 serves to dissipate heat of the power supply 6 and then the heat is dissipated out from the fan 321 at the rear side of the air channel 40. Thus, air flows in the casing 3 to have a preferred heat dissipation effect. Furthermore, the space in the casing 3 provides to install the motherboard 5.

Moreover in the present invention, two through holes 323 are formed on the back plate 32 behind the accessing unit 36 for installing a fan (not shown) so as to increase the heat dissipation of the casing 3.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A computer casing, comprising:
a front plate and a back plate; the back plate being installed with a plurality of slots; two sides of the front plate and back plate being installed with a first lateral plate and a second lateral plate; a bottom plate being installed at a bottom side of the casing;
an accessing unit installed at an inner corner side of the front plate and adjacent to the first lateral plate; a bottom of the accessing unit being corresponding to the grid holes of the bottom plate;
an isolating plate installed at an inner surface of the second lateral plate; a top end of the isolating plate being extended with a folded surface;
a front end of the isolating plate being installed with an enhancing plate; a periphery of the isolating plate being adhered to the second lateral plate; the bottom plate, the front plate and the back plate; an inner space of the casing being formed with an air channel; the isolating plate being formed with a via hole and a through hole; the via hole being at a front end of the isolating plate near the front plate; and the through hole being at a rear side of the isolating plate corresponding to the position of a motherboard;
a first fan being installed upon the back plate;
a power supply; output wires of the power supply serving to supply power to the motherboard and the accessing unit; and
the motherboard being positioned at a spaced enclosed by the accessing unit, power supply and the isolating plate; a second fan is installed on the through hole of the isolating plate corresponding to the motherboard.

2. The computer casing as claimed in claim 1, wherein a front end of the isolating plate is installed with an enhancing plate, and a periphery of the enhancing plate is adhered to the second lateral plate and the bottom plate.

3. The computer casing as claimed in claim 1, wherein a bottom plate has a plurality of grid holes and a plurality of pads and net holes; a bottom of the power supply is formed with a fan and is installed at position corresponding to the pads and net holes of the bottom plate; the pads make the power supply being at a position higher than the net holes.

4. The computer casing as claimed in claim 1, wherein at least one through hole is formed on the back plate behind the accessing unit for installing a fan.

5. The computer casing as claimed in claim 1, wherein a bottom plate has a plurality of grid holes.

6. The computer casing as claimed in claim 1, wherein a lateral side of the power supply has a frame which is installed to the via hole of the isolating plate.

7. The computer casing as claimed in claim 1, wherein the power supply is a PS/2 power supply.
